(19) United States
(12) Patent Application Publication
(10) Pub. No.: US 2023/0174101 A1
(43) Pub. Date: Jun. 8, 2023

(54) Framework For Modeling Subsystems of an Autonomous Vehicle System and the Impact of the Subsystems on Vehicle Performance

(71) Applicant: Motional AD LLC, Boston, MA (US)

(72) Inventors: Anne Collin, Cambridge, MA (US); Radboud Duintjer Tebbens, Winchester, MA (US)

(21) Appl. No.: 17/543,708

(22) Filed: Dec. 6, 2021

(51) Int. Cl. B60W 60/00; G06K 9/62; H04W 4/40

(52) U.S. Cl. CPC B60W 60/0011; B60W 60/0015; G06K 9/623; G06K 9/6277; H04W 4/40; B60W 2554/4049

(57) ABSTRACT

In an embodiment, a method comprises: selecting a scenario for simulating a vehicle and agent(s) in a virtual world environment; selecting a set of subsystem component models for the vehicle; simulating the scenario in the virtual world environment using the selected subsystem component models, wherein the simulating comprises: estimating a pose of the vehicle and the agent(s); determining a probability of detection of the agent(s) by sensor(s) of the vehicle based on a perception subsystem component model, the estimated pose of the vehicle/agent(s) and a latency model modeling latency of a message queuing network for communicating data between the subsystems; generating a set of candidate trajectories for the vehicle; evaluating each trajectory based on a number of rule violations associated with the trajectory; selecting one trajectory from the set of trajectories based on the number of rule violations; and analyzing outputs of the subsystem component models to determine their interdependencies.

### BACKGROUND

During development of an autonomous vehicle (AV) system it is often difficult to understand the impact of a particular subsystem of the AV on overall AV performance, and to identify performance improvements at the subsystem level that would improve the AV performance.

### BRIEF DESCRIPTION OF THE FIGURES

FIG. 1 is an example environment in which a vehicle including one or more components of an autonomous system can be implemented;

FIG. 2 is a diagram of one or more example systems of a vehicle including an autonomous system;

FIG. 3 is a diagram of example components of one or more devices and/or one or more systems of FIGS. 1 and 2;

FIG. 4 is a diagram of example components of an autonomous system;

FIG. 5 provides an overview of an example framework for modeling subsystems of an AV system and the impact of the subsystems on AV performance;

FIG. 6 illustrates an example model structure of an AV system and its subsystems;

FIG. 7 illustrates an example model structure of timing;

FIG. 8 illustrates an example rulebook;

FIGS. 9 and 10 illustrate an example scenario using the framework of FIGS. 5 and 6;

FIG. 11A illustrates use of a Markov model for determining recall;

FIG. 11B is a plot of probability of pedestrian recognition at current and past timesteps versus distance from pedestrian to model perception recall based on a Markov model;

FIG. 12 illustrates an example of perception recall modeling using the Markov model;

FIG. 13 illustrates an example trajectory proposal and selection scenario;

FIG. 14A is a bar graph illustrating an example rule R2 violation as a function of probability of detection for the example scenario shown in FIG. 13;

FIG. 14B is a scatter plot illustrating an example rule R2 violation as a function of perception period and recall error slope for the example scenario shown in FIG. 13;

FIG. 14C is a scatter plot illustrating an example rule R2 violation as a function of localization error and select period for the example scenario shown in FIG. 13;

FIG. 14D is a scatter plot illustrating an example rule R2 violation as a function of localization error and recall error slope for the example scenario shown in FIG. 13;

FIG. 15 illustrates an example correlation analysis on design variables;

FIGS. 16-18 illustrate example rule tradeoffs;

FIG. 19 illustrates an example application of the framework for determining system, subsystem and sensor level performance targets; and

FIG. 20 illustrates an example application of the framework for selecting a candidate AV architecture with highest performance among a plurality of candidate AV architectures.

FIG. 21 is a flow diagram of a process for determining interdependencies of subsystems of a vehicle.

### DETAILED DESCRIPTION

In the following description numerous specific details are set forth in order to provide a thorough understanding of the present disclosure for the purposes of explanation. It will be apparent, however, that the embodiments described by the present disclosure can be practiced without these specific details. In some instances, well-known structures and devices are illustrated in block diagram form in order to avoid unnecessarily obscuring aspects of the present disclosure.

Specific arrangements or orderings of schematic elements, such as those representing systems, devices, modules, instruction blocks, data elements, and/or the like are illustrated in the drawings for ease of description. However, it will be understood by those skilled in the art that the specific ordering or arrangement of the schematic elements in the drawings is not meant to imply that a particular order or sequence of processing, or separation of processes, is required unless explicitly described as such. Further, the inclusion of a schematic element in a drawing is not meant to imply that such element is required in all embodiments or that the features represented by such element may not be included in or combined with other elements in some embodiments unless explicitly described as such.

Further, where connecting elements such as solid or dashed lines or arrows are used in the drawings to illustrate a connection, relationship, or association between or among two or more other schematic elements, the absence of any such connecting elements is not meant to imply that no connection, relationship, or association can exist. In other words, some connections, relationships, or associations between elements are not illustrated in the drawings so as not to obscure the disclosure. In addition, for ease of illustration, a single connecting element can be used to represent multiple connections, relationships or associations between elements. For example, where a connecting element represents communication of signals, data, or instructions (e.g., “software instructions”), it should be understood by those skilled in the art that such element can represent one or multiple signal paths (e.g., a bus), as may be needed, to affect the communication.

Although the terms first, second, third, and/or the like are used to describe various elements, these elements should not be limited by these terms. The terms first, second, third, and/or the like are used only to distinguish one element from another. For example, a first contact could be termed a second contact and, similarly, a second contact could be termed a first contact without departing from the scope of the described embodiments. The first contact and the second contact are both contacts, but they are not the same contact.

The terminology used in the description of the various described embodiments herein is included for the purpose of describing particular embodiments only and is not intended to be limiting. As used in the description of the various described embodiments and the appended claims, the singular forms “a,” “an” and “the” are intended to include the plural forms as well and can be used interchangeably with “one or more” or “at least one,” unless the context clearly indicates otherwise. It will also be understood that the term “and/or” as used herein refers to and encompasses any and all possible combinations of one or more of the associated listed items. It will be further understood that the terms “includes,” “including,” “comprises,” and/or “comprising,” when used in this description specify the presence of stated features, integers, steps, operations, elements, and/or components, but do not preclude the presence or addition of one or more other features, integers, steps, operations, elements, components, and/or groups thereof.

As used herein, the terms “communication” and “communicate” refer to at least one of the reception, receipt, transmission, transfer, provision, and/or the like of information (or information represented by, for example, data, signals, messages, instructions, commands, and/or the like). For one unit (e.g., a device, a system, a component of a device or system, combinations thereof, and/or the like) to be in communication with another unit means that the one unit is able to directly or indirectly receive information from and/or send (e.g., transmit) information to the other unit. This may refer to a direct or indirect connection that is wired and/or wireless in nature. Additionally, two units may be in communication with each other even though the information transmitted may be modified, processed, relayed, and/or routed between the first and second unit. For example, a first unit may be in communication with a second unit even though the first unit passively receives information and does not actively transmit information to the second unit. As another example, a first unit may be in communication with a second unit if at least one intermediary unit (e.g., a third unit located between the first unit and the second unit) processes information received from the first unit and transmits the processed information to the second unit. In some embodiments, a message may refer to a network packet (e.g., a data packet and/or the like) that includes data.

As used herein, the term “if” is, optionally, construed to mean “when”, “upon”, “in response to determining,” “in response to detecting,” and/or the like, depending on the context. Similarly, the phrase “if it is determined” or “if [a stated condition or event] is detected” is, optionally, construed to mean “upon determining,” “in response to determining,” “upon detecting [the stated condition or event],” “in response to detecting [the stated condition or event],” and/or the like, depending on the context. Also, as used herein, the terms “has”, “have”, “having”, or the like are intended to be open-ended terms. Further, the phrase “based on” is intended to mean “based at least partially on” unless explicitly stated otherwise.

Reference will now be made in detail to embodiments, examples of which are illustrated in the accompanying drawings. In the following detailed description, numerous specific details are set forth in order to provide a thorough understanding of the various described embodiments. However, it will be apparent to one of ordinary skill in the art that the various described embodiments can be practiced without these specific details. In other instances, well-known methods, procedures, components, circuits, and networks have not been described in detail so as not to unnecessarily obscure aspects of the embodiments.

### General Overview

In some aspects and/or embodiments, systems, methods, and computer program products described herein include and/or implement a functional architecture for modeling AV subsystems and their interdependencies. The disclosed functional framework allows developers to better understand the impact of AV subsystem performance, as defined by rulebooks, identify performance improvements at the subsystem level that would yield an improvement in AV behavior and provide a quantitative, validated, model to create performance requirements based on pulling rule violation scores into subsystem performance metrics.

In an embodiment, the framework is applied to different AV driving scenarios in a Monte Carlo simulation to evaluate performance of the AV in the different driving scenarios (e.g., determine the number of rule violations by the AV). Users can change or update the model to improve performance of the AV for a given driving scenario and run the simulation again with the updated model to see if the performance is improved or degraded. Given a quantitative performance expectation (e.g., given by rulebooks), the system model provides a tool that allows AV technical stack developers to explore the design space of AVs to find the one design that best satisfies a performance expectation. The framework uses a series of equations that represent the performance of each subsystem in the AV technical stack and their interactions and interdependencies with other subsystems in the AV stack.

In an embodiment, the framework provides a high-level model of the AV stack that contains the main subsystems that drive performance. The framework takes as inputs a functional architecture, including variations on the architecture, expert opinion on which effects drive performance the most at the subsystem level, a list of relevant scenarios and a set of rules to evaluate AV performance in the given scenarios. The framework outputs performance requirements for the subsystems and rulebook performance comparison between different AV stack designs. For example, the framework can determine whether a particular design of the AV stack will incur a lower number of rule violations than other designs of the AV stack when using the same rulebook. The framework can also test subsystem high-level concepts and whether they impact rulebook scores in given scenarios.

In an embodiment, a method comprises: selecting, with at least one processor, a scenario for simulating a vehicle and at least one agent in a virtual world environment; selecting, with the at least one processor, a set of subsystem component models for the vehicle, wherein the subsystem component models include a localization subsystem component model, a perception subsystem component model, a trajectory proposer subsystem component model, and trajectory selector subsystem component model; simulating, with the at least one processor, the scenario in the virtual world environment using the selected subsystem component models, wherein the simulating comprises: estimating a pose of the vehicle and the at least one agent based on the localization subsystem component model; determining a probability of detection of the at least one agent by at least one sensor of the vehicle based on the perception subsystem component model, the estimated pose of the vehicle, the estimated pose of the at least one agent and a latency model of a message queuing network for communicating data between the subsystems; generating, with the at least one processor, a set of candidate trajectories for the vehicle to navigate the at least one agent based on the trajectory proposer subsystem component model; evaluating, with the at least one processor, each trajectory based on a number of rule violations associated with the trajectory; selecting, with the at least one processor, one trajectory from the set of trajectories based on the rule violations for each candidate trajectory; and analyzing, with the at least one processor, outputs of the subsystem component models to determine interdependencies between two or more subsystems of the vehicle.

In an embodiment, the simulating includes Monte Carlo simulations.

In an embodiment, the latency model includes performing a discrete-event simulation of the message queuing network, and a simulated event is selected based on a probability distribution for the event.

In an embodiment, the localization subsystem component model includes a covariance matrix for vehicle pose error, a computation time and task period.

In an embodiment, the perception subsystem component model includes a recall rate as a function of distance between the vehicle and the at least one agent and an agent detection at a previous timestep of the simulation, a list of classes, a confusion matrix between the classes and a covariance matrix on the pose of the agent.

In an embodiment, the recall rate as a function of distance is based on a Markov model.

In an embodiment, the set of trajectories is generated randomly.

In an embodiment, the trajectory selector subsystem component model includes a rulebook that is used to rank the set of candidate trajectories and select a particular trajectory from the set of candidate trajectories based on the ranking.

In an embodiment, analyzing outputs of the subsystem component models to determine interdependencies between two or more of the subsystem component models, further comprises: comparing a rule violations with a probability of detection.

In an embodiment, analyzing outputs of the subsystem component models to determine interdependencies between two or more of the subsystem component models, further comprises: comparing a perception period for the perception subsystem with a recall error slope.

In an embodiment, analyzing outputs of the subsystem component models to determine interdependencies between two or more of the subsystem component models, further comprises: comparing localization error with a select period for the trajectory selector subsystem.

In an embodiment, analyzing outputs of the subsystem component models to determine interdependencies between two or more of the subsystem component models, further comprises: comparing localization error with a recall error slope.

In an embodiment, analyzing outputs of the subsystem component models to determine interdependencies between two or more of the subsystem component models, further comprises: generating a correlation heatmap that correlates subsystem model parameters with rule violations.

In an embodiment, analyzing outputs of the subsystem component models to determine interdependencies between two or more of the subsystem component models, further comprises: comparing degrees of violation of at least two rules.

In an embodiment, a system comprises: at least one processor; and memory storing instructions that when executed by the at least one processor, cause the at least one processor to perform any one of the methods recited above.

In an embodiment, a non-transitory, computer-readable storage medium having stored thereon instructions that when executed by the one or more processors, cause the one or more processors to perform any one of the methods recited above.

By virtue of the implementation of systems, methods, and computer program products described herein provide at least the following advantages. The disclosed embodiments allow AV stack designs to be rated based on an expectation of good driving by leveraging rulebooks to guide which rules are in scope for any scenario, and which violations matter most. The disclosed embodiments also allow the use of sampling techniques to analyze the AV stack components in relevant scenarios, to construct an abstract model of the AV to realize behavior given subsystem performance, to run a sensitivity analysis and Monte Carlo simulations to obtain statistically significant (stochastic) rule violations given an AV model and scenario. The disclosed embodiments output curves or surfaces rather than one data point to provide a greater understanding of subsystem interdependencies. The framework can be implemented in a computer as a tool that can be used by decision makers to make tradeoffs between different design configurations, constraints, etc. Another advantage of the framework is that design solutions for new subsystems can be modeled and tested. For example, the following question can he answered: “What if the perception algorithm had 99.99% recall?” Using the disclosed framework, a developer can see the impact of a 99.99% recall for a perception system even though there is no perception code that can meet that specification.

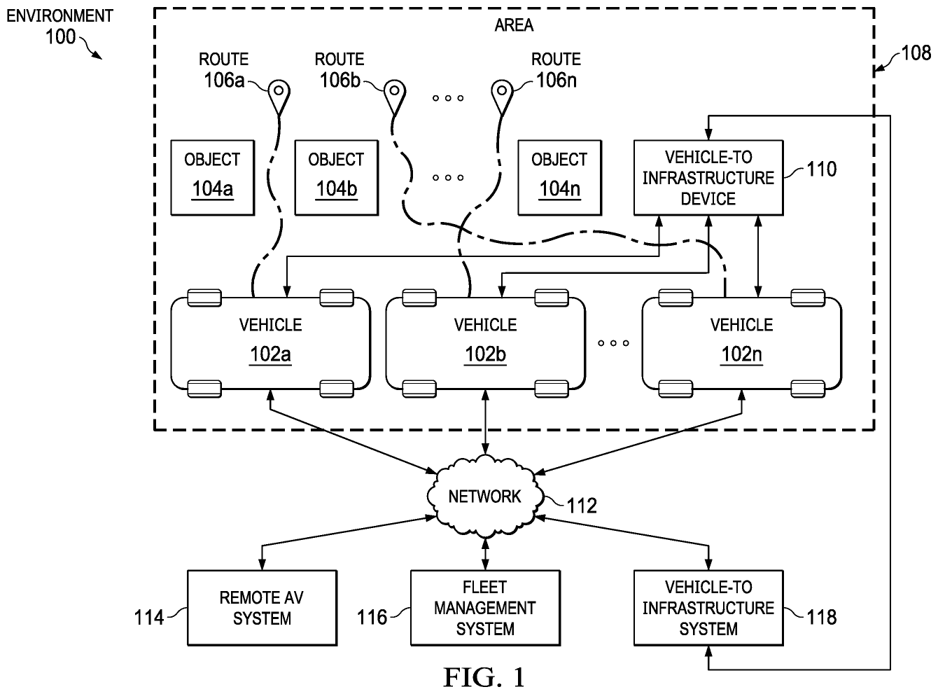

Referring now to FIG. 1, illustrated is example environment 100 in which vehicles that include autonomous systems, as well as vehicles that do not, are operated. As illustrated, environment 100 includes vehicles 102a-102n, objects 104a-104n, routes 106a-106n, area 108, vehicle-to-infrastructure (V2I) device 110, network 112, remote AV system 114, fleet management system 116, and V2I system 118. Vehicles 102a-102n, vehicle-to-infrastructure (V2I) device 110, network 112, AV system 114, fleet management system 116, and V2I system 118 interconnects (e.g., establish a connection to communicate and/or the like) via wired connections, wireless connections, or a combination of wired or wireless connections. In some embodiments, objects 104a-104n interconnect with at least one of vehicles 102a-102n, vehicle-to-infrastructure (V2I) device 110, network 112, AV system 114, fleet management system 116, and V2I system 118 via wired connections, wireless connections, or a combination of wired or wireless connections.

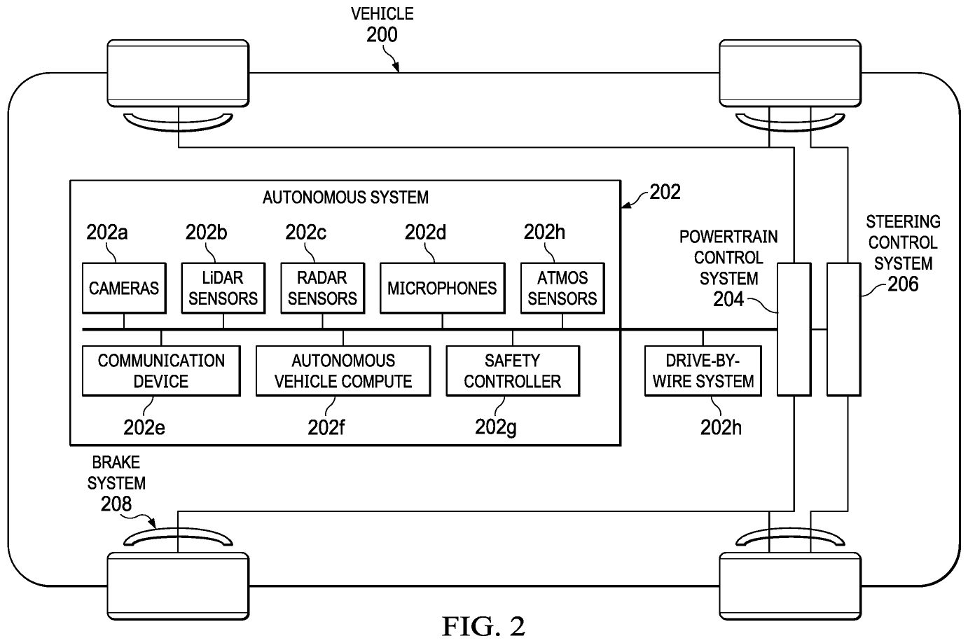

Vehicles 102a-102n (referred to individually as vehicle 102 and collectively as vehicles 102) include at least one device configured to transport goods and/or people. In some embodiments, vehicles 102 are configured to be in communication with V2I device 110, remote AV system 114, fleet management system 116, and/or V2I system 118 via network 112. In some embodiments, vehicles 102 include cars, buses, trucks, trains, and/or the like. In some embodiments, vehicles 102 are the same as, or similar to, vehicles 200, described herein (see FIG. 2). In some embodiments, a vehicle 200 of a set of vehicles 200 is associated with an autonomous fleet manager. In some embodiments, vehicles 102 travel along respective routes 106a-106n (referred to individually as route 106 and collectively as routes 106), as described herein. In some embodiments, one or more vehicles 102 include an autonomous system (e.g., an autonomous system that is the same as or similar to autonomous system 202).

Objects 104a-104n (referred to individually as object 104 and collectively as objects 104) include, for example, at least one vehicle, at least one pedestrian, at least one cyclist, at least one structure (e.g., a building, a sign, a fire hydrant, etc.), and/or the like. Each object 104 is stationary (e.g., located at a fixed location for a period of time) or mobile (e.g., having a velocity and associated with at least one trajectory). In some embodiments, objects 104 are associated with corresponding locations in area 108.

Routes 106a-106n (referred to individually as route 106 and collectively as routes 106) are each associated with (e.g., prescribe) a sequence of actions (also known as a trajectory) connecting states along which an AV can navigate. Each route 106 starts at an initial state (e.g., a state that corresponds to a first spatiotemporal location, velocity, and/or the like) and a final goal state (e.g., a state that corresponds to a second spatiotemporal location that is different from the first spatiotemporal location) or goal region (e.g., a subspace of acceptable states (e.g., terminal states)). In some embodiments, the first state includes a location at which an individual or individuals are to be picked-up by the AV and the second state or region includes a location or locations at which the individual or individuals picked-up by the AV are to be dropped-off. In some embodiments, routes 106 include a plurality of acceptable state sequences (e.g., a plurality of spatiotemporal location sequences), the plurality of state sequences associated with (e.g., defining) a plurality of trajectories. In an example, routes 106 include only high level actions or imprecise state locations, such as a series of connected roads dictating turning directions at roadway intersections. Additionally, or alternatively, routes 106 may include more precise actions or states such as, for example, specific target lanes or precise locations within the lane areas and targeted speed at those positions. In an example, routes 106 include a plurality of precise state sequences along the at least one high level action sequence with a limited lookahead horizon to reach intermediate goals, where the combination of successive iterations of limited horizon state sequences cumulatively correspond to a plurality of trajectories that collectively form the high level route to terminate at the final goal state or region.

Area 108 includes a physical area (e.g., a geographic region) within which vehicles 102 can navigate. In an example, area 108 includes at least one state (e.g., a country, a province, an individual state of a plurality of states included in a country, etc.), at least one portion of a state, at least one city, at least one portion of a city, etc. In some embodiments, area 108 includes at least one named thoroughfare (referred to herein as a “road”) such as a highway, an interstate highway, a parkway, a city street, etc. Additionally, or alternatively, in some examples area 108 includes at least one unnamed road such as a driveway, a section of a parking lot, a section of a vacant and/or undeveloped lot, a dirt path, etc. In some embodiments, a road includes at least one lane (e.g., a portion of the road that can be traversed by vehicles 102). In an example, a road includes at least one lane associated with (e.g., identified based on) at least one lane marking.

Vehicle-to-Infrastructure (V2I) device 110 (sometimes referred to as a Vehicle-to-Infrastructure (V2X) device) includes at least one device configured to be in communication with vehicles 102 and/or V2I infrastructure system 118. In some embodiments, V2I device 110 is configured to be in communication with vehicles 102, remote AV system 114, fleet management system 116, and/or V2I system 118 via network 112. In some embodiments, V2I device 110 includes a radio frequency identification (RFID) device, signage, cameras (e.g., two-dimensional (2D) and/or three-dimensional (3D) cameras), lane markers, streetlights, parking meters, etc. In some embodiments, V2I device 110 is configured to communicate directly with vehicles 102. Additionally, or alternatively, in some embodiments V2I device 110 is configured to communicate with vehicles 102, remote AV system 114, and/or fleet management system 116 via V2I system 118. In some embodiments, V2I device 110 is configured to communicate with V2I system 118 via network 112.

Network 112 includes one or more wired and/or wireless networks. In an example, network 112 includes a cellular network (e.g., a long term evolution (LTE) network, a third generation (3G) network, a fourth generation (4G) network, a fifth generation (5G) network, a code division multiple access (CDMA) network, etc.), a public land mobile network (PLMN), a local area network (LAN), a wide area network (WAN), a metropolitan area network (MAN), a telephone network (e.g., the public switched telephone network (PSTN), a private network, an ad hoc network, an intranet, the Internet, a fiber optic-based network, a cloud computing network, etc., a combination of some or all of these networks, and/or the like.

Remote AV system 114 includes at least one device configured to be in communication with vehicles 102, V2I device 110, network 112, remote AV system 114, fleet management system 116, and/or V2I system 118 via network 112. In an example, remote AV system 114 includes a server, a group of servers, and/or other like devices. In some embodiments, remote AV system 114 is co-located with the fleet management system 116. In some embodiments, remote AV system 114 is involved in the installation of some or all of the components of a vehicle, including an autonomous system, an autonomous vehicle compute, software implemented by an autonomous vehicle compute, and/or the like. In some embodiments, remote AV system 114 maintains (e.g., updates and/or replaces) such components and/or software during the lifetime of the vehicle.

Fleet management system 116 includes at least one device configured to be in communication with vehicles 102, V2I device 110, remote AV system 114, and/or V2I infrastructure system 118. In an example, fleet management system 116 includes a server, a group of servers, and/or other like devices. In some embodiments, fleet management system 116 is associated with a ridesharing company (e.g., an organization that controls operation of multiple vehicles (e.g., vehicles that include autonomous systems and/or vehicles that do not include autonomous systems) and/or the like).

In some embodiments, V2I system 118 includes at least one device configured to be in communication with vehicles 102, V2I device 110, remote AV system 114, and/or fleet management system 116 via network 112. In some examples, V2I system 118 is configured to be in communication with V2I device 110 via a connection different from network 112. In some embodiments, V2I system 118 includes a server, a group of servers, and/or other like devices. In some embodiments, V2I system 118 is associated with a municipality or a private institution (e.g., a private institution that maintains V2I device 110 and/or the like).

The number and arrangement of elements illustrated in FIG. 1 are provided as an example. There can be additional elements, fewer elements, different elements, and/or differently arranged elements, than those illustrated in FIG. 1. Additionally, or alternatively, at least one element of environment 100 can perform one or more functions described as being performed by at least one different element of FIG. 1. Additionally, or alternatively, at least one set of elements of environment 100 can perform one or more functions described as being performed by at least one different set of elements of environment 100.

Referring now to FIG. 2, vehicle 200 includes autonomous system 202, powertrain control system 204, steering control system 206, and brake system 208. In some embodiments, vehicle 200 is the same as or similar to vehicle 102 (see FIG. 1). In some embodiments, vehicle 102 have autonomous capability (e.g., implement at least one function, feature, device, and/or the like that enable vehicle 200 to be partially or fully operated without human intervention including, without limitation, fully autonomous vehicles (e.g., vehicles that forego reliance on human intervention), highly autonomous vehicles (e.g., vehicles that forego reliance on human intervention in certain situations), and/or the like). For a detailed description of fully autonomous vehicles and highly autonomous vehicles, reference may be made to SAE International's standard J3016: Taxonomy and Definitions for Terms Related to On-Road Motor Vehicle Automated Driving Systems, which is incorporated by reference in its entirety. In some embodiments, vehicle 200 is associated with an autonomous fleet manager and/or a ridesharing company.

Autonomous system 202 includes a sensor suite that includes one or more devices such as cameras 202a, LiDAR sensors 202b, radar sensors 202c, and microphones 202d. In some embodiments, autonomous system 202 can include more or fewer devices and/or different devices (e.g., ultrasonic sensors, inertial sensors, GPS receivers (discussed below), odometry sensors that generate data associated with an indication of a distance that vehicle 200 has traveled, and/or the like). In some embodiments, autonomous system 202 uses the one or more devices included in autonomous system 202 to generate data associated with environment 100, described herein. The data generated by the one or more devices of autonomous system 202 can be used by one or more systems described herein to observe the environment (e.g., environment 100) in which vehicle 200 is located. In some embodiments, autonomous system 202 includes communication device 202e, autonomous vehicle compute 202f, and drive-by-wire (DBW) system 202h.

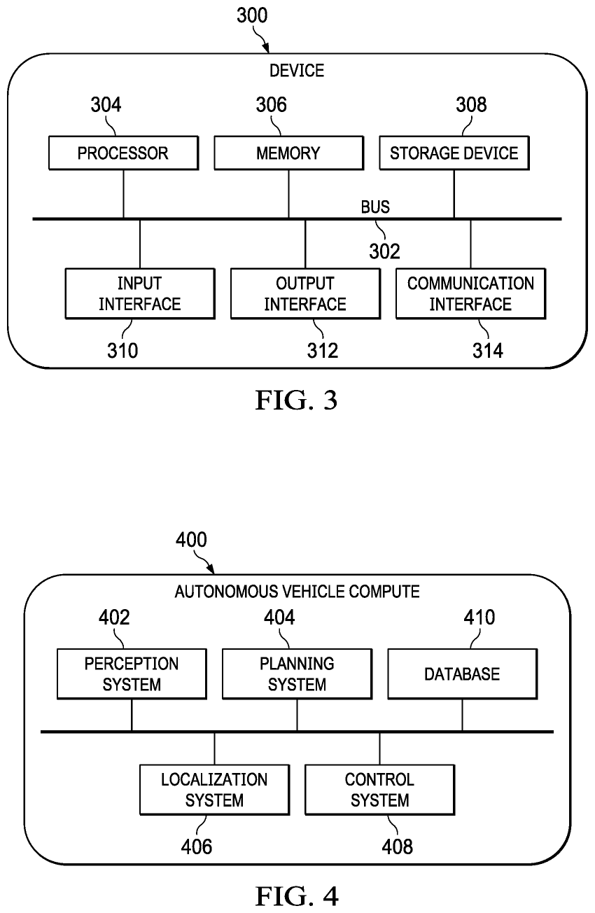

Cameras 202a include at least one device configured to be in communication with communication device 202e, autonomous vehicle compute 202f, and/or safety controller 202g via a bus (e.g., a bus that is the same as or similar to bus 302 of FIG. 3). Cameras 202a include at least one camera (e.g., a digital camera using a light sensor such as a charge-coupled device (CCD), a thermal camera, an infrared (IR) camera, an event camera, and/or the like) to capture images including physical objects (e.g., cars, buses, curbs, people, and/or the like). In some embodiments, camera 202a generates camera data as output. In some examples, camera 202a generates camera data that includes image data associated with an image. In this example, the image data may specify at least one parameter (e.g., image characteristics such as exposure, brightness, etc., an image timestamp, and/or the like) corresponding to the image. In such an example, the image may be in a format (e.g., RAW, JPEG, PNG, and/or the like). In some embodiments, camera 202a includes a plurality of independent cameras configured on (e.g., positioned on) a vehicle to capture images for the purpose of stereopsis (stereo vision). In some examples, camera 202a includes a plurality of cameras that generate image data and transmit the image data to autonomous vehicle compute 202f and/or a fleet management system (e.g., a fleet management system that is the same as or similar to fleet management system 116 of FIG. 1). In such an example, autonomous vehicle compute 202f determines depth to one or more objects in a field of view of at least two cameras of the plurality of cameras based on the image data from the at least two cameras. In some embodiments, cameras 202a is configured to capture images of objects within a distance from cameras 202a (e.g., up to 100 meters, up to a kilometer, and/or the like). Accordingly, cameras 202a include features such as sensors and lenses that are optimized for perceiving objects that are at one or more distances from cameras 202a.

In an embodiment, camera 202a includes at least one camera configured to capture one or more images associated with one or more traffic lights, street signs and/or other physical objects that provide visual navigation information. In some embodiments, camera 202a generates traffic light data associated with one or more images. In some examples, camera 202a generates TLD data associated with one or more images that include a format (e.g., RAW, JPEG, PNG, and/or the like). In some embodiments, camera 202a that generates TLD data differs from other systems described herein incorporating cameras in that camera 202a can include one or more cameras with a wide field of view (e.g., a wide-angle lens, a fish-eye lens, a lens having a viewing angle of approximately 120 degrees or more, and/or the like) to generate images about as many physical objects as possible.

Laser Detection and Ranging (LiDAR) sensors 202b include at least one device configured to be in communication with communication device 202e, autonomous vehicle compute 202f, and/or safety controller 202g via a bus (e.g., a bus that is the same as or similar to bus 302 of FIG. 3). LiDAR sensors 202b include a system configured to transmit light from a light emitter (e.g., a laser transmitter). Light emitted by LiDAR sensors 202b include light (e.g., infrared light and/or the like) that is outside of the visible spectrum. In some embodiments, during operation, light emitted by LiDAR sensors 202b encounters a physical object (e.g., a vehicle) and is reflected back to LiDAR sensors 202b. In some embodiments, the light emitted by LiDAR sensors 202b does not penetrate the physical objects that the light encounters. LiDAR sensors 202b also include at least one light detector which detects the light that was emitted from the light emitter after the light encounters a physical object. In some embodiments, at least one data processing system associated with LiDAR sensors 202b generates an image (e.g., a point cloud, a combined point cloud, and/or the like) representing the objects included in a field of view of LiDAR sensors 202b. In some examples, the at least one data processing system associated with LiDAR sensor 202b generates an image that represents the boundaries of a physical object, the surfaces (e.g., the topology of the surfaces) of the physical object, and/or the like. In such an example, the image is used to determine the boundaries of physical objects in the field of view of LiDAR sensors 202b.

Radio Detection and Ranging (radar) sensors 202c include at least one device configured to be in communication with communication device 202e, autonomous vehicle compute 202f, and/or safety controller 202g via a bus (e.g., a bus that is the same as or similar to bus 302 of FIG. 3). Radar sensors 202c include a system configured to transmit radio waves (either pulsed or continuously). The radio waves transmitted by radar sensors 202c include radio waves that are within a predetermined spectrum In some embodiments, during operation, radio waves transmitted by radar sensors 202c encounter a physical object and are reflected back to radar sensors 202c. In some embodiments, the radio waves transmitted by radar sensors 202c are not reflected by some objects. In some embodiments, at least one data processing system associated with radar sensors 202c generates signals representing the objects included in a field of view of radar sensors 202c. For example, the at least one data processing system associated with radar sensor 202c generates an image that represents the boundaries of a physical object, the surfaces (e.g., the topology of the surfaces) of the physical object, and/or the like. In some examples, the image is used to determine the boundaries of physical objects in the field of view of radar sensors 202c.

Microphones 202d includes at least one device configured to be in communication with communication device 202e, autonomous vehicle compute 202f, and/or safety controller 202g via a bus (e.g., a bus that is the same as or similar to bus 302 of FIG. 3). Microphones 202d include one or more microphones (e.g., array microphones, external microphones, and/or the like) that capture audio signals and generate data associated with (e.g., representing) the audio signals. In some examples, microphones 202d include transducer devices and/or like devices. In some embodiments, one or more systems described herein can receive the data generated by microphones 202d and determine a position of an object relative to vehicle 200 (e.g., a distance and/or the like) based on the audio signals associated with the data.

Communication device 202e include at least one device configured to be in communication with cameras 202a, LiDAR sensors 202b, radar sensors 202c, microphones 202d, autonomous vehicle compute 202f, safety controller 202g, and/or DBW system 202h. For example, communication device 202e may include a device that is the same as or similar to communication interface 314 of FIG. 3. In some embodiments, communication device 202e includes a vehicle-to-vehicle (V2V) communication device (e.g., a device that enables wireless communication of data between vehicles).

Autonomous vehicle compute 202f include at least one device configured to be in communication with cameras 202a, LiDAR sensors 202b, radar sensors 202c, microphones 202d, communication device 202e, safety controller 202g, and/or DBW system 202h. In some examples, autonomous vehicle compute 202f includes a device such as a client device, a mobile device (e.g., a cellular telephone, a tablet, and/or the like) a server (e.g., a computing device including one or more central processing units, graphical processing units, and/or the like), and/or the like. In some embodiments, autonomous vehicle compute 202f is the same as or similar to autonomous vehicle compute 400, described herein. Additionally, or alternatively, in some embodiments autonomous vehicle compute 202f is configured to be in communication with an autonomous vehicle system (e.g., an autonomous vehicle system that is the same as or similar to remote AV system 114 of FIG. 1), a fleet management system (e.g., a fleet management system that is the same as or similar to fleet management system 116 of FIG. 1), a V2I device (e.g., a V2I device that is the same as or similar to V2I device 110 of FIG. 1), and/or a V2I system (e.g., a V2I system that is the same as or similar to V2I system 118 of FIG. 1).

Safety controller 202g includes at least one device configured to be in communication with cameras 202a, LiDAR sensors 202b, radar sensors 202c, microphones 202d, communication device 202e, autonomous vehicle computer 202f, and/or DBW system 202h. In some examples, safety controller 202g includes one or more controllers (electrical controllers, electromechanical controllers, and/or the like) that are configured to generate and/or transmit control signals to operate one or more devices of vehicle 200 (e.g., powertrain control system 204, steering control system 206, brake system 208, and/or the like). In some embodiments, safety controller 202g is configured to generate control signals that take precedence over (e.g., overrides) control signals generated and/or transmitted by autonomous vehicle compute 202f.

DBW system 202h includes at least one device configured to be in communication with communication device 202e and/or autonomous vehicle compute 202f. In some examples, DBW system 202h includes one or more controllers (e.g., electrical controllers, electromechanical controllers, and/or the like) that are configured to generate and/or transmit control signals to operate one or more devices of vehicle 200 (e.g., powertrain control system 204, steering control system 206, brake system 208, and/or the like). Additionally, or alternatively, the one or more controllers of DBW system 202h are configured to generate and/or transmit control signals to operate at least one different device (e.g., a turn signal, headlights, door locks, windshield wipers, and/or the like) of vehicle 200.

Powertrain control system 204 includes at least one device configured to be in communication with DBW system 202h. In some examples, powertrain control system 204 includes at least one controller, actuator, and/or the like. In some embodiments, powertrain control system 204 receives control signals from DBW system 202h and powertrain control system 204 causes vehicle 200 to start moving forward, stop moving forward, start moving backward, stop moving backward, accelerate in a direction, decelerate in a direction, perform a left turn, perform a right turn, and/or the like. In an example, powertrain control system 204 causes the energy (e.g., fuel, electricity, and/or the like) provided to a motor of the vehicle to increase, remain the same, or decrease, thereby causing at least one wheel of vehicle 200 to rotate or not rotate.

Steering control system 206 includes at least one device configured to rotate one or more wheels of vehicle 200. In some examples, steering control system 206 includes at least one controller, actuator, and/or the like. In some embodiments, steering control system 206 causes the front two wheels and/or the rear two wheels of vehicle 200 to rotate to the left or right to cause vehicle 200 to turn to the left or right.

Brake system 208 includes at least one device configured to actuate one or more brakes to cause vehicle 200 to reduce speed and/or remain stationary. In some examples, brake system 208 includes at least one controller and/or actuator that is configured to cause one or more calipers associated with one or more wheels of vehicle 200 to close on a corresponding rotor of vehicle 200. Additionally, or alternatively, in some examples brake system 208 includes an automatic emergency braking (AEB) system, a regenerative braking system, and/or the like.

In some embodiments, vehicle 200 includes at least one platform sensor (not explicitly illustrated) that measures or infers properties of a state or a condition of vehicle 200. In some examples, vehicle 200 includes platform sensors such as a global positioning system (GPS) receiver, an inertial measurement unit (IMU), a wheel speed sensor, a wheel brake pressure sensor, a wheel torque sensor, an engine torque sensor, a steering angle sensor, and/or the like.

Referring now to FIG. 3, illustrated is a schematic diagram of a device 300. As illustrated, device 300 includes computer processor 304, memory 306, storage component 308, input interface 310, output interface 312, communication interface 314, and bus 302. In some embodiments, device 300 corresponds to at least one device of vehicles 102 (e.g., at least one device of a system of vehicles 102), at least one device of, and/or one or more devices of network 112 (e.g., one or more devices of a system of network 112). In some embodiments, one or more devices of vehicles 102 (e.g., one or more devices of a system of vehicles 102), and/or one or more devices of network 112 (e.g., one or more devices of a system of network 112) include at least one device 300 and/or at least one component of device 300. As shown in FIG. 3, device 300 includes bus 302, computer processor 304, memory 306, storage component 308, input interface 310, output interface 312, and communication interface 314.

Bus 302 includes a component that permits communication among the components of device 300. In some embodiments, computer processor 304 is implemented in hardware, software, or a combination of hardware and software. In some examples, computer processor 304 includes a computer processor (e.g., a central processing unit (CPU), a graphics processing unit (GPU), an accelerated processing unit (APU), and/or the like), a microphone, a digital signal processor (DSP), and/or any processing component (e.g., a field-programmable gate array (FPGA), an application specific integrated circuit (ASIC), and/or the like) that can be programmed to perform at least one function. Memory 306 includes random access memory (RAM), read-only memory (ROM), and/or another type of dynamic and/or static storage device (e.g., flash memory, magnetic memory, optical memory, and/or the like) that stores data and/or instructions for use by computer processor 304.

Storage component 308 stores data and/or software related to the operation and use of device 300. In some examples, storage component 308 includes a hard disk (e.g., a magnetic disk, an optical disk, a magneto-optic disk, a solid state disk, and/or the like), a compact disc (CD), a digital versatile disc (DVD), a floppy disk, a cartridge, a magnetic tape, a CD-ROM, RAM, PROM, EPROM, FLASH-EPROM, NV-RAM, and/or another type of computer readable medium, along with a corresponding drive.

Input interface 310 includes a component that permits device 300 to receive information, such as via user input (e.g., a touchscreen display, a keyboard, a keypad, a mouse, a button, a switch, a microphone, a camera, and/or the like). Additionally, or alternatively, in some embodiments input interface 310 includes a sensor that senses information (e.g., a global positioning system (GPS) receiver, an accelerometer, a gyroscope, an actuator, and/or the like). Output interface 312 includes a component that provides output information from device 300 (e.g., a display, a speaker, one or more light-emitting diodes (LEDs), and/or the like).

In some embodiments, communication interface 314 includes a transceiver-like component (e.g., a transceiver, a separate receiver and transmitter, and/or the like) that permits device 300 to communicate with other devices via a wired connection, a wireless connection, or a combination of wired and wireless connections. In some examples, communication interface 314 permits device 300 to receive information from another device and/or provide information to another device. In some examples, communication interface 314 includes an Ethernet interface, an optical interface, a coaxial interface, an infrared interface, a radio frequency (RF) interface, a universal serial bus (USB) interface, a Wi-Fi® interface, a cellular network interface, and/or the like.

In some embodiments, device 300 performs one or more processes described herein. Device 300 performs these processes based on computer processor 304 executing software instructions stored by a computer-readable medium, such as memory 305 and/or storage component 308. A computer-readable medium (e.g., a non-transitory computer readable medium) is defined herein as a non-transitory memory device. A non-transitory memory device includes memory space located inside a single physical storage device or memory space spread across multiple physical storage devices.

In some embodiments, software instructions are read into memory 306 and/or storage component 308 from another computer-readable medium or from another device via communication interface 314. When executed, software instructions stored in memory 306 and/or storage component 308 cause computer processor 304 to perform one or more processes described herein. Additionally, or alternatively, hardwired circuitry is used in place of or in combination with software instructions to perform one or more processes described herein. Thus, embodiments described herein are not limited to any specific combination of hardware circuitry and software unless explicitly stated otherwise.

Memory 306 and/or storage component 308 includes data storage or at least one data structure (e.g., a database and/or the like). Device 300 is capable of receiving information from, storing information in, communicating information to, or searching information stored in the data storage or the at least one data structure in memory 306 or storage component 308. In some examples, the information includes network data, input data, output data, or any combination thereof.

In some embodiments, device 300 is configured to execute software instructions that are either stored in memory 306 and/or in the memory of another device (e.g., another device that is the same as or similar to device 300). As used herein, the term “module” refers to at least one instruction stored in memory 306 and/or in the memory of another device that, when executed by computer processor 304 and/or by a computer processor of another device (e.g., another device that is the same as or similar to device 300) cause device 300 (e.g., at least one component of device 300) to perform one or more processes described herein. In some embodiments, a module is implemented in software, firmware, hardware, and/or the like.

The number and arrangement of components illustrated in FIG. 3 are provided as an example. In some embodiments, device 300 can include additional components, fewer components, different components, or differently arranged components than those illustrated in FIG. 3. Additionally, or alternatively, a set of components (e.g., one or more components) of device 300 can perform one or more functions described as being performed by another component or another set of components of device 300.

Referring now to FIG. 4, illustrated is an example block diagram of an autonomous vehicle compute 400 (sometimes referred to as an “AV stack”). As illustrated, autonomous vehicle compute 400 includes perception system 402 (sometimes referred to as a perception module), planning system 404 (sometimes referred to as a planning module), localization system 406 (sometimes referred to as a localization module), control system 408 (sometimes referred to as a control module), and database 410. In some embodiments, perception system 402, planning system 404, localization system 406, control system 408, and database 410 are included and/or implemented in an autonomous navigation system of a vehicle (e.g., autonomous vehicle compute 202f of vehicle 200). Additionally, or alternatively, in some embodiments perception system 402, planning system 404, localization system 406, control system 408, and database 410 are included in one or more standalone systems (e.g., one or more systems that are the same as or similar to autonomous vehicle compute 400 and/or the like). In some examples, perception system 402, planning system 404, localization system 406, control system 408, and database 410 are included in one or more standalone systems that are located in a vehicle and/or at least one remote system as described herein. In some embodiments, any and/or all of the systems included in autonomous vehicle compute 400 are implemented in software (e.g., in software instructions stored in memory), computer hardware (e.g., by microprocessors, microcontrollers, application-specific integrated circuits [ASICs], Field Programmable Gate Arrays (FPGAs), and/or the like), or combinations of computer software and computer hardware. It will also be understood that, in some embodiments, autonomous vehicle compute 400 is configured to be in communication with a remote system (e.g., an autonomous vehicle system that is the same as or similar to remote AV system 114, a fleet management system 116 that is the same as or similar to fleet management system 116, a V2I system that is the same as or similar to V2I system 118, and/or the like).

In some embodiments, perception system 402 receives data associated with at least one physical object (e.g., data that is used by perception system 402 to detect the at least one physical object) in an environment and classifies the at least one physical object. In some examples, perception system 402 receives image data captured by at least one camera (e.g., cameras 202a), the image associated with (e.g., representing) one or more physical objects within a field of view of the at least one camera. In such an example, perception system 402 classifies at least one physical object based on one or more groupings of physical objects (e.g., bicycles, vehicles, traffic signs, pedestrians, and/or the like). In some embodiments, perception system 402 transmits data associated with the classification of the physical objects to planning system 404 based on perception system 402 classifying the physical objects.

In some embodiments, planning system 404 receives data associated with a destination and generates data associated with at least one route (e.g., routes 106) along which a vehicle (e.g., vehicles 102) can travel along toward a destination. In some embodiments, planning system 404 periodically or continuously receives data from perception system 402 (e.g., data associated with the classification of physical objects, described above) and planning system 404 updates the at least one trajectory or generates at least one different trajectory based on the data generated by perception system 402. In some embodiments, planning system 404 receives data associated with an updated position of a vehicle (e.g., vehicles 102) from localization system 406 and planning system 404 updates the at least one trajectory or generates at least one different trajectory based on the data generated by localization system 406.

In some embodiments, localization system 406 receives data associated with (e.g., representing) a location of a vehicle (e.g., vehicles 102) in an area. In some examples, localization system 406 receives LiDAR data associated with at least one point cloud generated by at least one LiDAR sensor (e.g., LiDAR sensors 202b). In certain examples, localization system 406 receives data associated with at least one point cloud from multiple LiDAR sensors and localization system 406 generates a combined point cloud based on each of the point clouds. In these examples, localization system 406 compares the at least one point cloud or the combined point cloud to two-dimensional (2D) and/or a three-dimensional (3D) map of the area stored in database 410. Localization system 406 then determines the position of the vehicle in the area based on localization system 406 comparing the at least one point cloud or the combined point cloud to the map. In some embodiments, the map includes a combined point cloud of the area generated prior to navigation of the vehicle. In some embodiments, maps include, without limitation, high-precision maps of the roadway geometric properties, maps describing road network connectivity properties, maps describing roadway physical properties (such as traffic speed, traffic volume, the number of vehicular and cyclist traffic lanes, lane width, lane traffic directions, or lane marker types and locations, or combinations thereof), and maps describing the spatial locations of road features such as crosswalks, traffic signs or other travel signals of various types. In some embodiments, the map is generated in real-time based on the data received by the perception system.

In another example, localization system 406 receives Global Navigation Satellite System (GNSS) data generated by a global positioning system (GPS) receiver. In some examples, localization system 406 receives GNSS data associated with the location of the vehicle in the area and localization system 406 determines a latitude and longitude of the vehicle in the area. In such an example, localization system 406 determines the position of the vehicle in the area based on the latitude and longitude of the vehicle. In some embodiments, localization system 406 generates data associated with the position of the vehicle. In some examples, localization system 406 generates data associated with the position of the vehicle based on localization system 406 determining the position of the vehicle. In such an example, the data associated with the position of the vehicle includes data associated with one or more semantic properties corresponding to the position of the vehicle.

In some embodiments, control system 408 receives data associated with at least one trajectory from planning system 404 and control system 408 controls operation of the vehicle. In some examples, control system 408 receives data associated with at least one trajectory from planning system 404 and control system 408 controls operation of the vehicle by generating and transmitting control signals to cause a powertrain control system (e.g., DBW system 202h, powertrain control system 204, and/or the like), a steering control system (e.g., steering control system 206), and/or a brake system (e.g., brake system 208) to operate. In an example, where a trajectory includes a left turn, control system 408 transmits a control signal to cause steering control system 206 to adjust a steering angle of vehicle 200, thereby causing vehicle 200 to turn left. Additionally, or alternatively, control system 408 generates and transmits control signals to cause other devices (e.g., headlights, turn signal, door locks, windshield wipers, and/or the like) of vehicle 200 to change states.

In some embodiments, perception system 402, planning system 404, localization system 406, and/or control system 408 implement at least one machine learning model (e.g., at least one multilayer perceptron (MLP), at least one convolutional neural network (CNN), at least one recurrent neural network (RNN), at least one autoencoder, at least one transformer, and/or the like). In some examples, perception system 402, planning system 404, localization system 406, and/or control system 408 implement at least one machine learning model alone or in combination with one or more of the above-noted systems. In some examples, perception system 402, planning system 404, localization system 406, and/or control system 408 implement at least one machine learning model as part of a pipeline (e.g., a pipeline for identifying one or more objects located in an environment and/or the like).

Database 410 stores data that is transmitted to, received from, and/or updated by perception system 402, planning system 404, localization system 406 and/or control system 408. In some examples, database 410 includes a storage component (e.g., a storage component that is the same as or similar to storage component 308 of FIG. 3) that stores data and/or software related to the operation and uses at least one system of autonomous vehicle compute 400. In some embodiments, database 410 stores data associated with 2D and/or 3D maps of at least one area. In some examples, database 410 stores data associated with 2D and/or 3D maps of a portion of a city, multiple portions of multiple cities, multiple cities, a county, a state, a State (e.g., a country), and/or the like). In such an example, a vehicle (e.g., a vehicle that is the same as or similar to vehicles 102 and/or vehicle 200) can drive along one or more drivable regions (e.g., single-lane roads, multi-lane roads, highways, back roads, off road trails, and/or the like) and cause at least one LiDAR sensor (e.g., a LiDAR sensor that is the same as or similar to LiDAR sensors 202b) to generate data associated with an image representing the objects included in a field of view of the at least one LiDAR sensor.

In some embodiments, database 410 can be implemented across a plurality of devices. In some examples, database 410 is included in a vehicle (e.g., a vehicle that is the same as or similar to vehicles 102 and/or vehicle 200), an autonomous vehicle system (e.g., an autonomous vehicle system that is the same as or similar to remote AV system 114, a fleet management system (e.g., a fleet management system that is the same as or similar to fleet management system 116 of FIG. 1, a V2I system (e.g., a V2I system that is the same as or similar to V2I system 118 of FIG. 1) and/or the like.

### System Model Overview

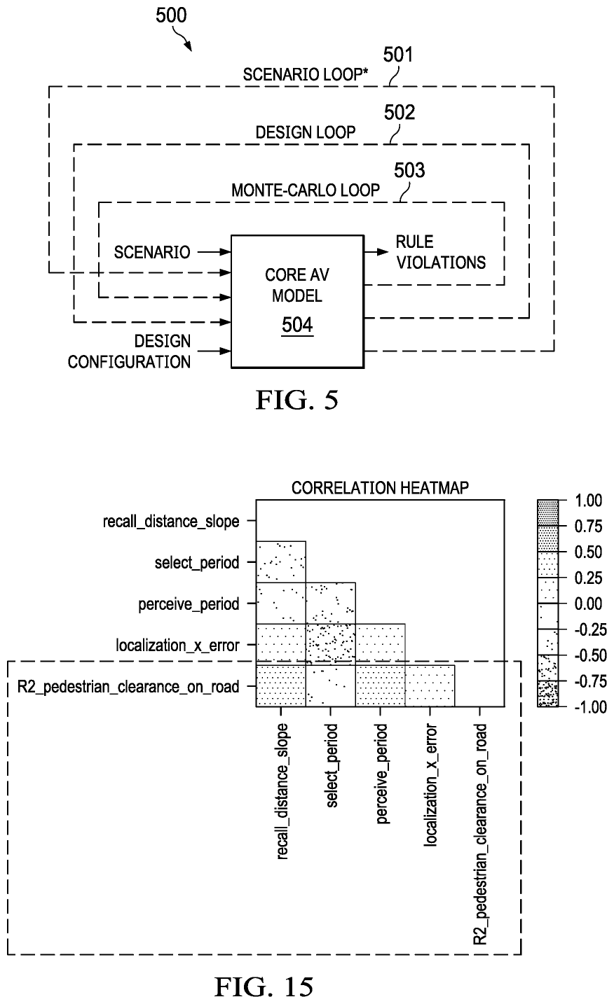

FIG. 5 provides an overview of an example framework 500 for modeling subsystems of an AV system and the impact of its subsystems on AV performance. Framework 500 includes a computer simulation of a core AV model 504 using three iterative loops: scenario loop 501, design loop 502 and Monte Carlo loop 503. For each iteration of scenario loop 501, a new scenario (e.g., lane change, collision avoidance) is selected to be simulated. For each iteration of design loop 502 within scenario loop 501, a design configuration for core AV model 504 is selected (e.g., selecting particular planning, localization and perception subsystem designs) for simulation using the selected scenario. For each iteration of Monte Carlo loop 503 within design loop 502 and scenario loop 501, Monte Carlo simulations are performed on an ego vehicle and one or more agents in a virtual world environment. The Monte Carlo simulations are used to predict the probability of different outcomes when uncertain variables in the selected design configuration are present to explain the impact of risk and uncertainty on AV performance for the selected scenario. In an embodiment, the Monte Carlo simulations are used to identify statistically significant rule violations for the selected design configuration and scenario.

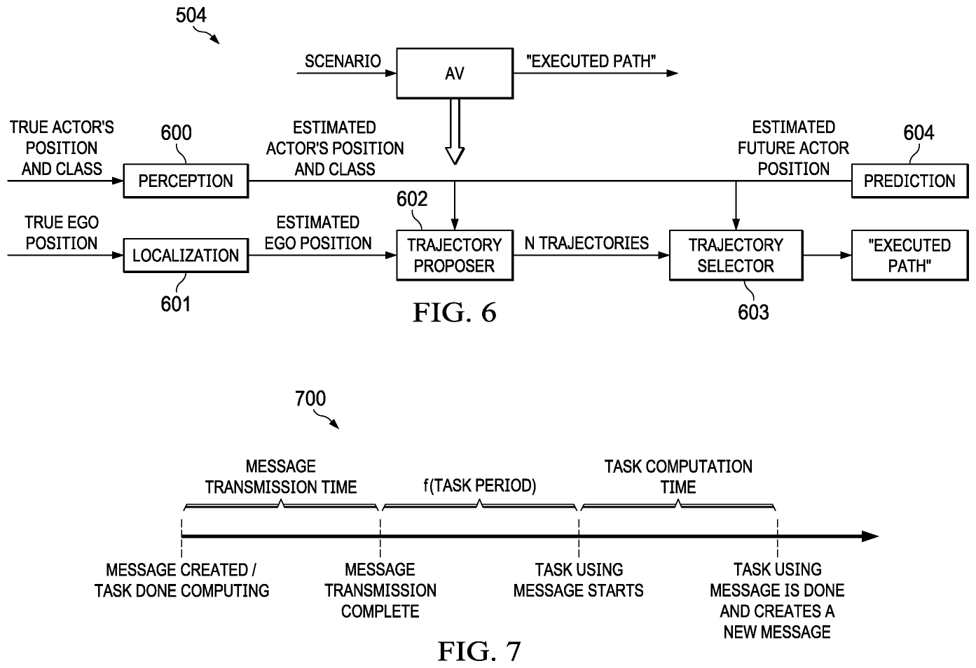

FIG. 6 illustrates an example core AV model 504. In an embodiment, core AV model 504 is a high-level system model designed to capture relationships between subsystems at a deep enough level to allow AV stack developers to make informative design decisions, and to ensure that enough potential solutions are explored in the design space. In an embodiment, core AV model 504 includes perception subsystem 600, localization subsystem 601, trajectory proposer 602, trajectory selector 603 and predictor 604. Perception subsystem 600 and localization subsystem 601 can be, for example, perception system 402 and localization system 406, described in reference to FIG. 4. The combination of trajectory proposer 602 and trajectory selector 603 can be, for example, the combination of planning system 404 and control system 408.

Perception subsystem 600 takes as input a ground truth of at least one agent pose (e.g., position, heading, velocity, acceleration) and class (e.g., pedestrian, driver, bicyclist), and outputs an estimated current agent pose according to a specified error distribution for the agent class and pose. In an embodiment, the performance of perception subsystem 600 is characterized by recall rate over distance, a confusion matrix (e.g., a class error distribution), an error matrix on pose estimation and a latency of communication between subsystems. The recall rate is defined as the probability of detecting an agent with at least one sensor of the ego vehicle. Latency is defined as the difference between the time of detection of the agent by perception subsystem 600 and the time that a message with the agent's pose and class is sent from the perception subsystem 600 to planner subsystem (605,605), as described in reference to FIG. 7.

In an embodiment, perception subsystem 600 is composed of three different functions: detect, classify and estimate. The detect function follows a Markov process with only two states at each timestep of the simulation: detected or not detected, as described. The classify and estimate functions are activated only if an object is detected, and an error model is used to track their respective error matrices. The estimated pose is sampled using a multivariate Gaussian distribution that is centered around the ground truth pose of the agent with the covariance matrix providing the pose variance. Some example parameters of perception subsystem 600 include but are not limited to: recall rate (defined above as a function of distance and previous timestep object detection), a list of agent classes and a confusion matrix between the classes, a covariance matrix on object state for use in state estimation, computation time and computation period (time to complete a task).

Localization subsystem 603 is modeled as a “black box’ and takes as input ground truth ego vehicle pose (e.g., position, heading, velocity, acceleration) and outputs an estimated current ego vehicle pose according to a specified error distribution for the ego vehicle pose. The ego vehicle pose is characterized by an error matrix on pose estimation and a latency (defined above). The estimated pose is sampled using a multivariate Gaussian distribution, centered around a ground truth pose with the covariance matrix providing the variance. In another embodiment, instead of using the covariance matrix directly, the covariance matrix can be reconstructed with eigenvalues that represent the size of the uncertainty ellipsoid around the pose estimate, and eigenvectors that represent the direction of the axes of that ellipsoid. For example, the covariance, Sigma, can be reconstructed by: Sigma=P^−1 DP, where P is the matrix of eigenvectors (each eigenvector is a column, in order) and D is the diagonal matrix of eigenvalues (in order).

In an embodiment, parameters of localization subsystem 603 include but are not limited to: a covariance matrix for ego vehicle pose error, computation time and computation period. In an embodiment, localization subsystem 603 takes sensor errors and outputs localization performance metrics (e.g., accuracy or uncertainty around the pose estimate), which in an embodiment can be approximated with a factor graph formulation, where each factor represents a sensor pipeline (e.g., IMU, LiDAR).

In an embodiment, trajectory proposer 602 and trajectory selector 605 together provide a “propose and select” architecture for proposing a plurality of candidate trajectories and selecting one trajectory based on a score determined by the number of rulebook violations made by the ego vehicle due to the trajectory. More particularly, trajectory proposer 602 takes as input the estimated current ego vehicle pose and the estimated current agent pose and class and proposes N candidate trajectories for the ego vehicle to take for the particular driving scenario. The “quality” of a particular trajectory proposer is measured by the degree of violation of the best candidate trajectories that are proposed (hereafter, also referred to as a “rule violation score”), which can be assumed to be a fixed number K. Trajectory proposer 602 is also associated with latency, which is the difference between the time messages from localization subsystem 601 and trajectory proposer 602 are received, and the time the trajectories are proposed. The more trajectories that are proposed, the better the k best trajectories are going to be, but the slower the trajectory selector 603 will select a trajectory as the executed path.

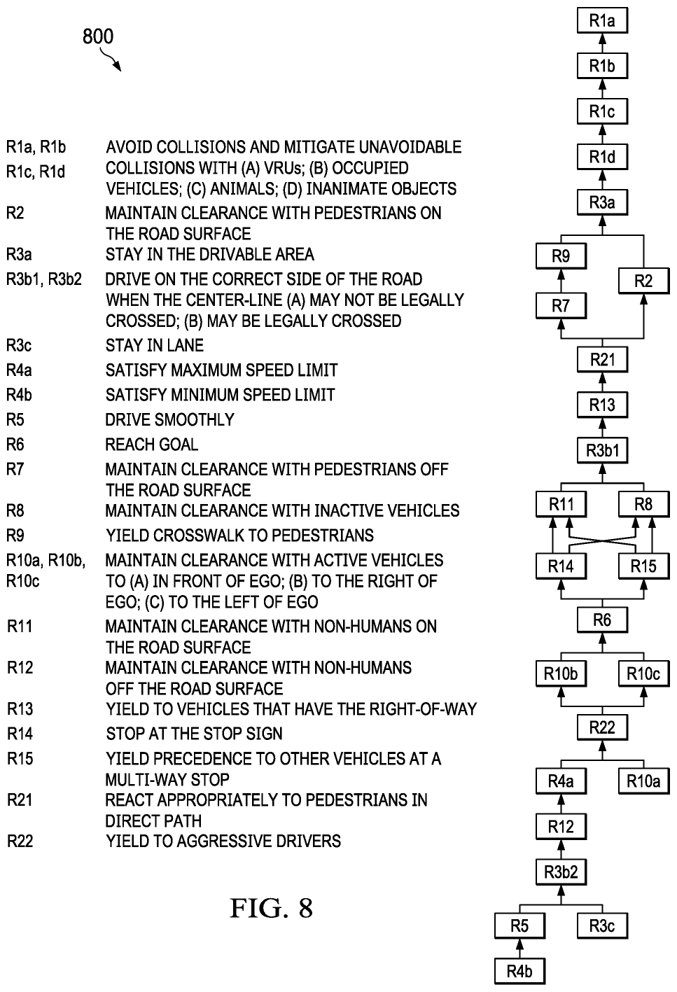

Trajectory selector 605 takes as input the N candidate trajectories and an estimated future agent position provided by predictor 604, and selects one of the N candidate trajectories to be the executed path of the ego vehicle for the particular driving scenario based on rule violation scores, as described in more detail in reference to FIG. 8. Given its imperfect inputs, trajectory selector 605 uses the rule violation scores to determine which of the proposed k candidate trajectories to select as the executed path for the ego vehicle. In an embodiment, in a first iteration a lexicographical comparison is used to choose the trajectory that has the least violation of the highest-level rules in a total order rulebook, such as the rulebook described in Censi et al. Liability, Ethics, and Culture-Aware Behavior Specification Using Rulebooks, https//arxiv.org/pdf/1902.09455.

FIG. 7 illustrates latency model 700 for modeling latency of the AV stack. In an embodiment, a discrete-event simulation is used to model latency in a message queuing network, where the different event types are: “message creation/task done computing,” “message transmission complete,” “task using message starts” and “task using message is done and creates a new message.” The goal of latency model 700 is to model the latency of the AV stack at a deep enough level to assess the impact of different task periods for each task on rule violations for a given scenario. Each time there is an event (e.g., perception starts, selecting ends, message arrives, etc., a clock is moved forward. For perception, localization and trajectory proposer subsystems, each time one of these functions is activated, events are randomly selected from given probability distributions (e.g., using the Metropolis algorithm).

FIG. 8 illustrates an example rulebook 800 for use in determining rule violation scores for candidate trajectories. Performance of the ego vehicle can be defined in different ways based on the example rulebook 800. In an embodiment, the rules in the rulebook are ordered in a hierarchy of importance, where the highest (i.e., most important rules) R1a, R1b, R1c, and R1d are to avoid and mitigate collisions, and the lowest or least important rule R4b is to satisfy a certain minimum speed limit. In some cases, two or more rules can have the same level of importance, such as, for example, R5 (drive smoothly) and R3c (stay in lane). The k candidate trajectories output by trajectory proposer 602 are each evaluated using the rulebook by counting the number of rule violations and assigning a rule violation score to each candidate trajectory, where the higher the score the better the candidate trajectory, and the candidate trajectory with the highest rule violation score is the executed path. In another embodiment, the number of rule violations can be ranked without assigning a score using, for example, a lexicographical comparison.

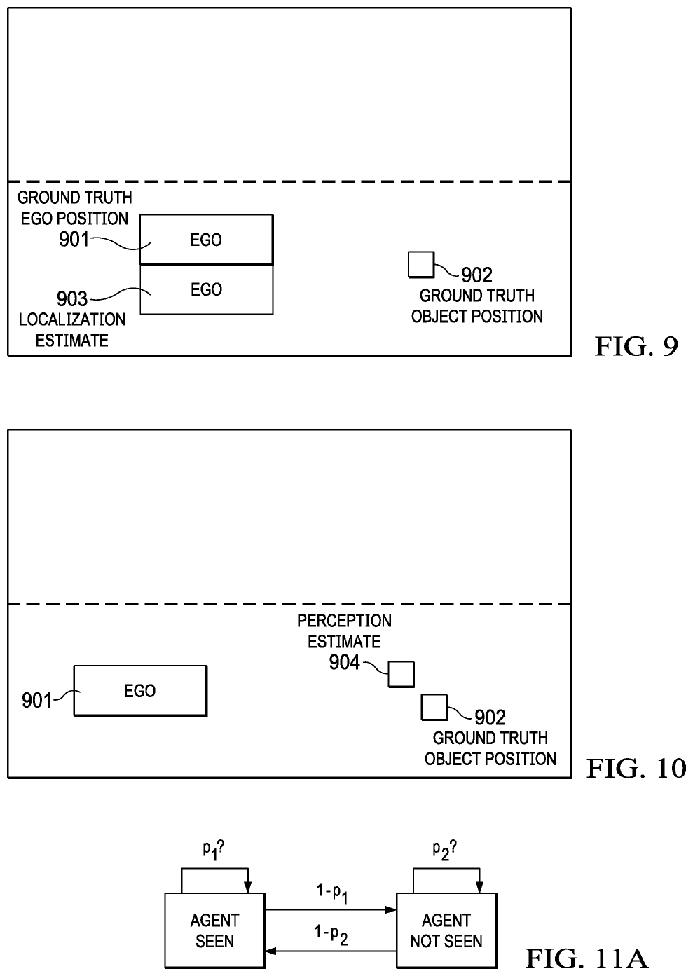

FIGS. 9 and 10 illustrate an example scenario where an ego vehicle 901 must avoid collision with pedestrian 902 and maintain a specified clearance. Perception subsystem 600 generates perception estimate 903 and localization subsystem 603 generates a localization estimate 904.

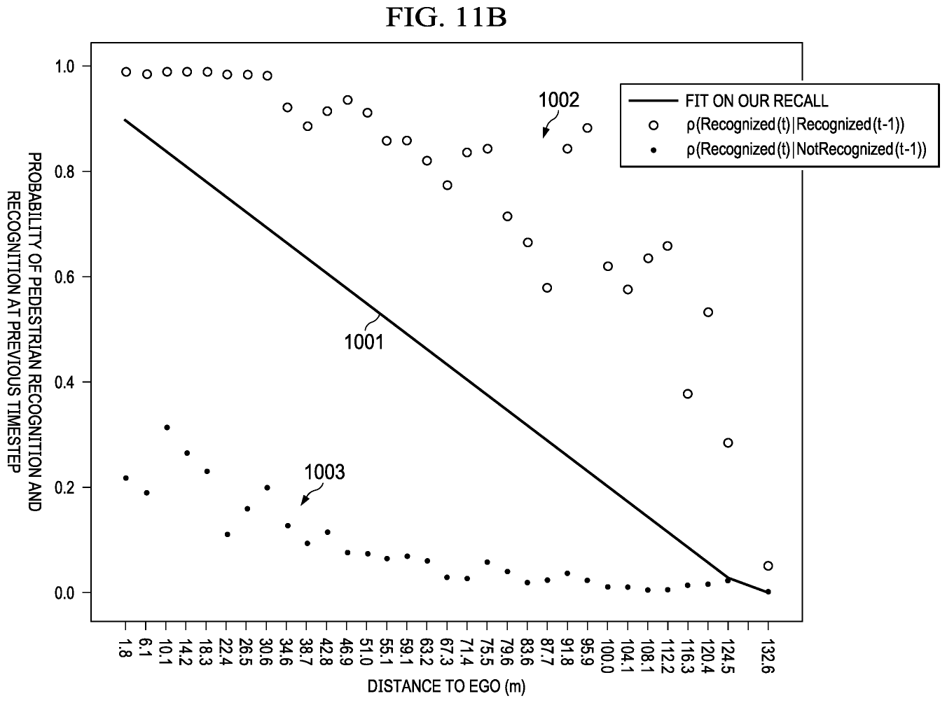

FIG. 11A illustrates modeling of perception subsystem recall (detecting of an agent) using a Markov chain, where P1 is the probability of recognizing the pedestrian and P2 is the probability of not recognizing the pedestrian 902.

FIG. 11B is a plot of the probability P of recognizing the pedestrian 902 at the current and previous timesteps of the simulation versus distance to the ego vehicle (in meters). The ground truth recall rate is modeled by line 1001, where data points 1002, 1003 (probabilities of recognizing pedestrian 902 at time t and t−1) are given by:
P(Recognized(t)|Recognized (t−1)), and
P(Recognized(t)|NotRecognized (t−1)).

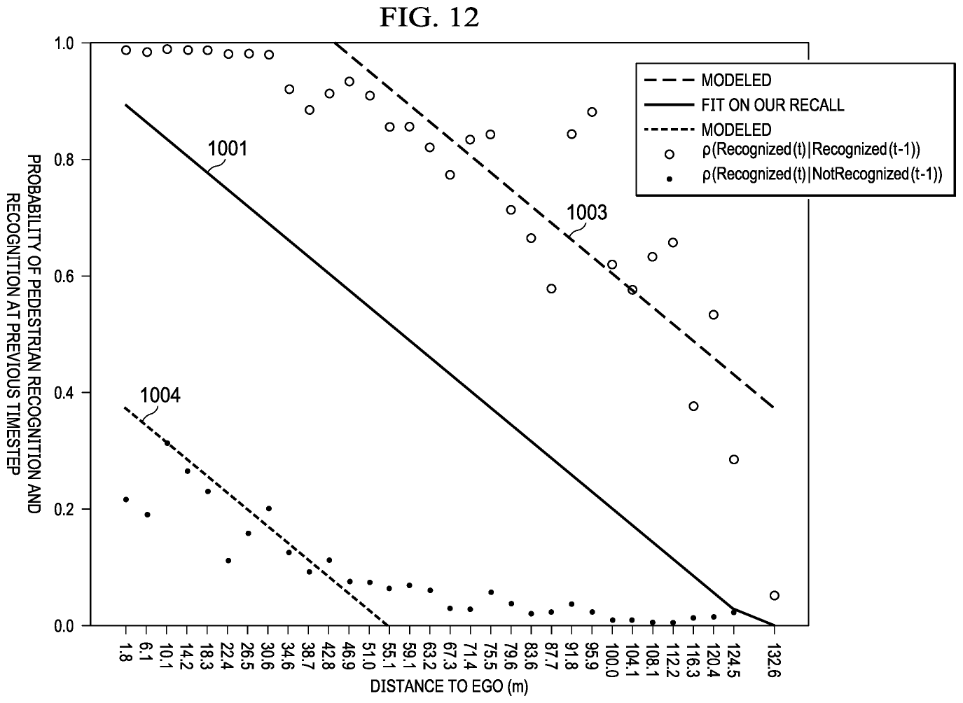

FIG. 12 shows ground truth recall model 1001, and recall models 1003, 1004, which model the probability of recognizing pedestrian 902 at the current timestep given that pedestrian 902 was recognized at the previous timestep, and the probability that pedestrian 902 is recognized at the current timestep given that pedestrian 902 was not recognized at the previous time step. In this example, if pedestrian 902 is detected at t−1, then P(X=1) increases by 0.40027073, and if pedestrian 902 is not recognized at t−1, P(X=1) decreases by 0.5213696, as expected, where X is the distance from pedestrian 902.

Note that the model for detecting an agent/object is the slope of lines 1003, 1004 (i.e., linear equations). At each timestep of the simulation, the distance from pedestrian 902 is calculated and used with models 1003, 1004 (linear equations) to determine probabilities of detecting pedestrian 902. The model that is used depends on whether pedestrian 902 was detected in the previous timestep of the simulation. For example, if at t−1 pedestrian 902 was not detected, then model 1003 would be used to determine the probability of detection at the current timestep. If at t−1 pedestrian 902 was detected, then model 1004 would be used to determine the probability of detection at the current timestep.

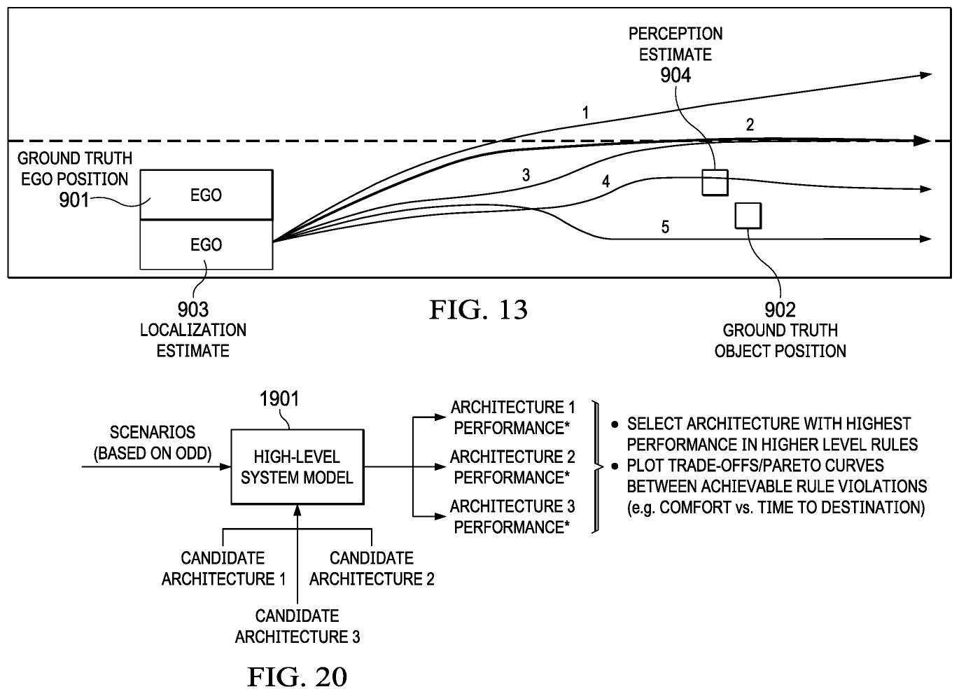

FIG. 13 illustrates modeling of trajectory proposer 602 and trajectory selector 605, which collectively are used to model the planner subsystem 404. The input into trajectory proposer subsystem 602 is perturbed outputs from perception subsystem 600 and localization subsystem 601. In an embodiment, the trajectory proposals are random. One parameter is the number of trajectories proposed N, which could be a number of “good” trajectories k, where “good” is in comparison with an optimal rulebook trajectory that is calculated offline with ideal parameters. Other parameters for the model are computation time and task period. In the example shown, N=5 and the candidate trajectories are labeled 1-5. Candidate trajectory 2 is selected as the best trajectory by trajectory selector 605.

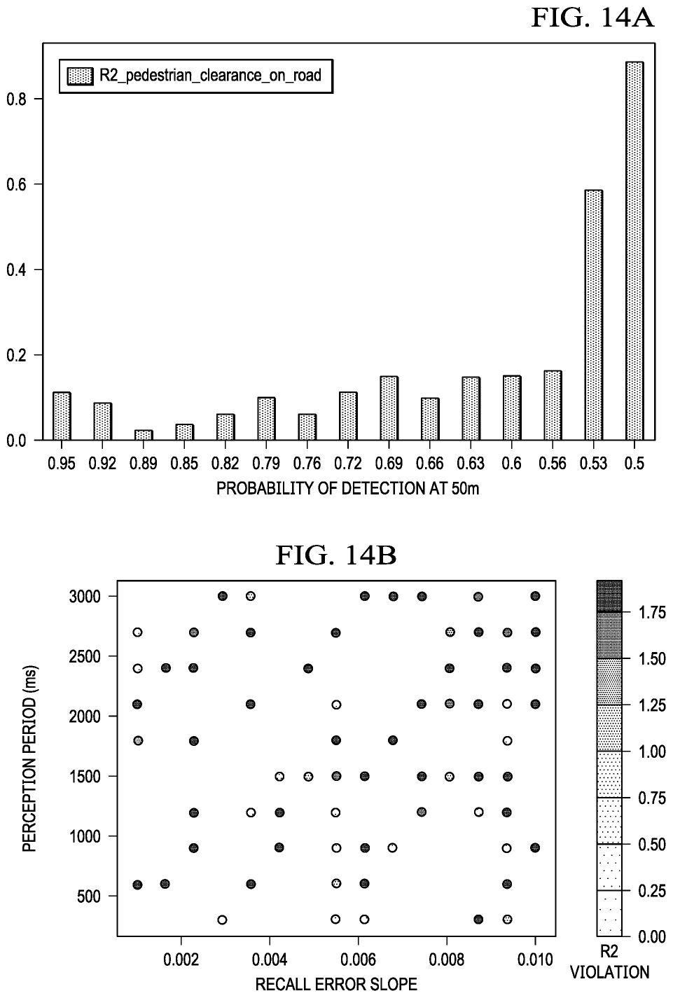

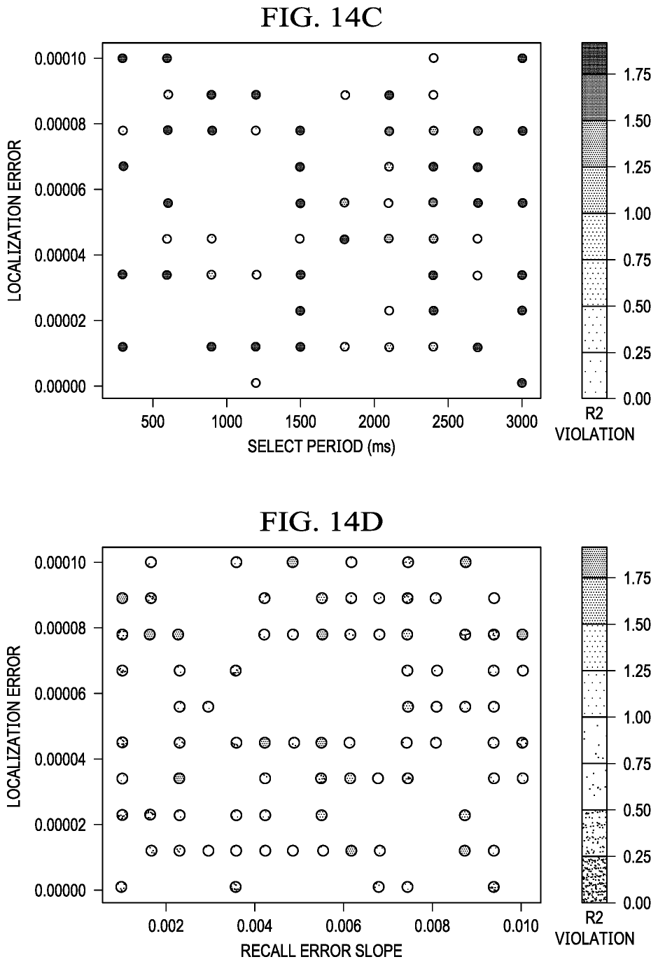

FIG. 14A is a bar graph of rule R2 violation scores versus the probability of detection at 50 meters, where rule R2 is to maintain clearance from pedestrians (FIG. 8) for a scenario where a pedestrian is in the lane of the ego vehicle. In this example, the selection period for selecting a trajectory is 300 ms, the perception task period is 400 ms and the longitudinal localization error is negligible. In this example, the bar graph in FIG. 14A shows not much gain between 0.56 and 0.95 (all else being equal), where it is desirable to be at or above 0.56 to ensure that rule R2 is not violated.

FIG. 14B is a plot of perception period (ms) versus recall error slope for the pedestrian clearance scenario. This plot attempts to answer the question of whether it is better to have a fast perception system or a higher recall. The data points are shaded based on the number of rule R2 violations, where the darker shade indicates a higher number of R2 violations than the lighter shades. In this example scenario, a mild trend is observed, where the worse the error slope and the higher the perception period, the higher the R2 violation. This is evident by the density of darker data points in the top right corner of the plot. However, since other parameters also vary, this example plot shows that the AV performance emerges from the intersection of all system performances.

FIG. 14C is an example plot of localization error versus selection period (ms). This plot attempts to answer the question of whether AV performance would be better with more accurate localization or a faster selector. From this plot it can be concluded that AV performance is dependent on more than these two parameters. Thus, it is not clear that AV performance would improve with more accurate localization or a faster selector.

FIG. 14D is an example plot of localization error versus recall error slope. This plot attempts to answer the question of whether engineering resources should be used to improve perception by X % or localization by Y %. From this plot it can be concluded that AV performance is dependent on more than these two parameters, as there is no apparent trend in the data. Thus, it is not clear, for example, that more engineering resources should be allocated to improving perception by X % or localization by Y %.

FIG. 15 illustrates a correlation heatmap on design variables. This plot shows that the two design variables that most correlate with a high R2 rule violation (darker shades of gray) are recall error and the perception activation period.

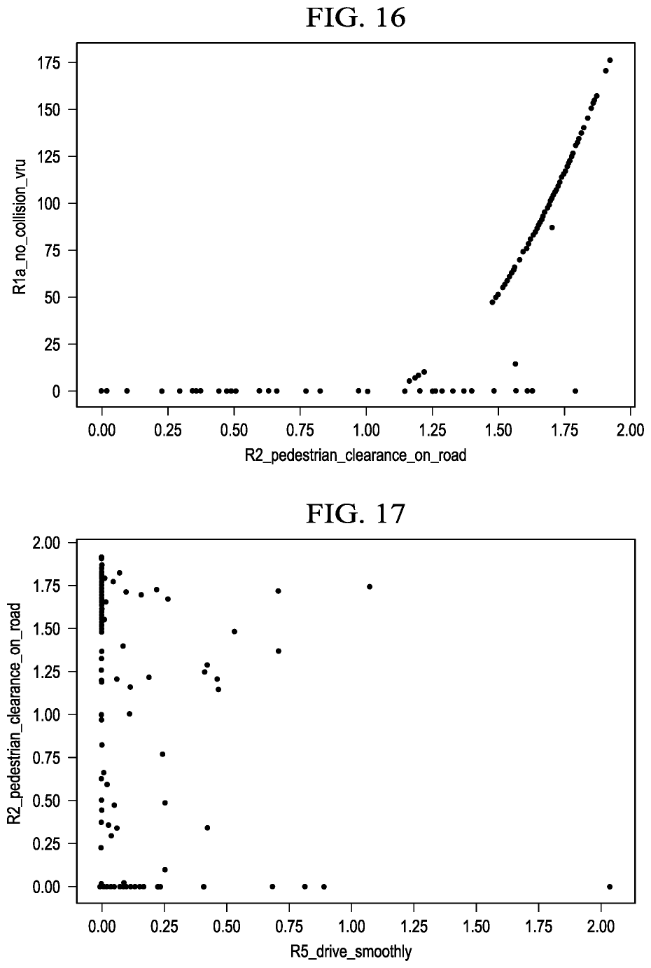

FIG. 16 is an example plot of rule R1a violations versus R2 pedestrian clearance on road violations (i.e., the severity or rule R1 violation as a function of R2 violation). The plot illustrates a rule trade-off where designs that lead to a low R2 violation also lead to a low R1 violation.

FIG. 17 is an example plot of a severity/degree of a R2 violation (pedestrian clearance) as a function of the severity/degree of a rule R5 violation (drive smoothly). In this example, most of the candidate trajectories do not have an R5 violation. Thus, respecting rule R2 does not necessarily mean violating rule R5. Thus, a trajectory that avoids collision with pedestrian 902 with proper clearance can also be executed by maneuvering the AV smoothly.

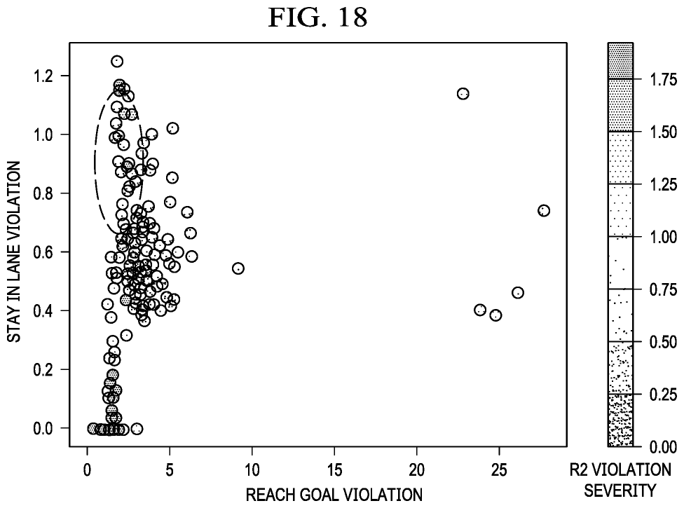

FIG. 18 is an example plot of severity/degree of a R109 violation (stay in lane) as a function of severity/degree of a R6 violation. In this example, it is impossible to maintain clearance, stay in lane and reach the goal at the same time. Thus, desirable architectures do not have a clearance violation, with a low reach goal violation.

### Example Applications

Some example applications for the framework described herein include but are not limited to: determining where to put research and development engineering resources in AV stack development, technology road mapping for future products, platforming methods to minimize re-work while serving different market segments, optimization of the AV performance given cost/energy consumption constraints and live health monitoring on the AV to identify when performance of a subsystem falls below the requirement and assess the resulting impact on driving behavior performance.

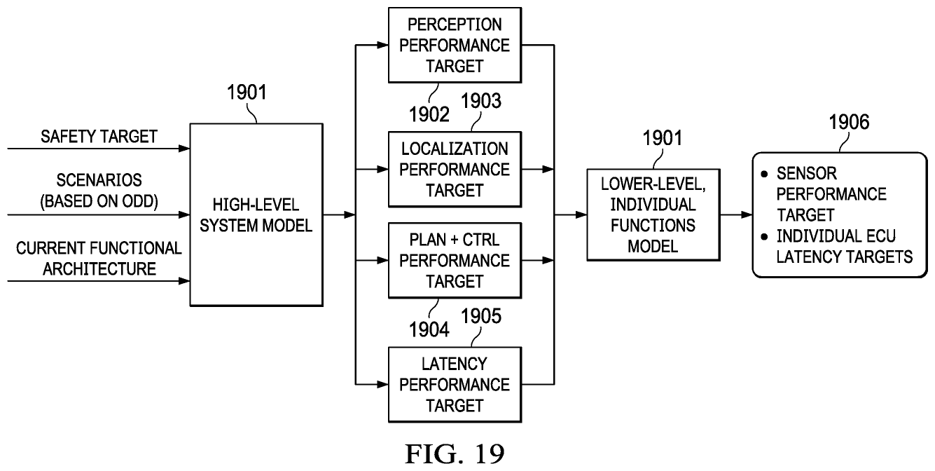

FIG. 19 illustrates an application of the framework for determining system, subsystem and sensor level performance targets. As shown in FIG. 19, each subsystem (planning, localization, perception, control) can be broken down into lower level models to answer questions, such as which sensors to select, which processor can yield a lower latency at the system level, etc. In the example shown, framework 1900 includes high-level system model 1901 (described in reference to FIGS. 5-18), which can be used to determine perception performance target 1902, localization performance target 1903, planning and control performance target 1904 and latency performance target 1905. Lower-level individual function models 1906 can then be simulated to meet the performance targets 1902-1905. From the lower-level individual function models 1906, sensor performance and individual electronic control unit (ECU) latency targets 1907 can be determined.

FIG. 20 illustrates an application of the framework for selecting an AV architecture with highest performance among a plurality of candidate AV architectures. High-level system model 1901 can be used to evaluate AV performance for various AV stack designs, enabling selection of the candidate architecture with, for example, the highest AV performance in higher level rules (e.g., collision avoidance), allow plotting of trade-offs and Pareto curves between achievable rule violations (e.g., comfort versus time to destination).

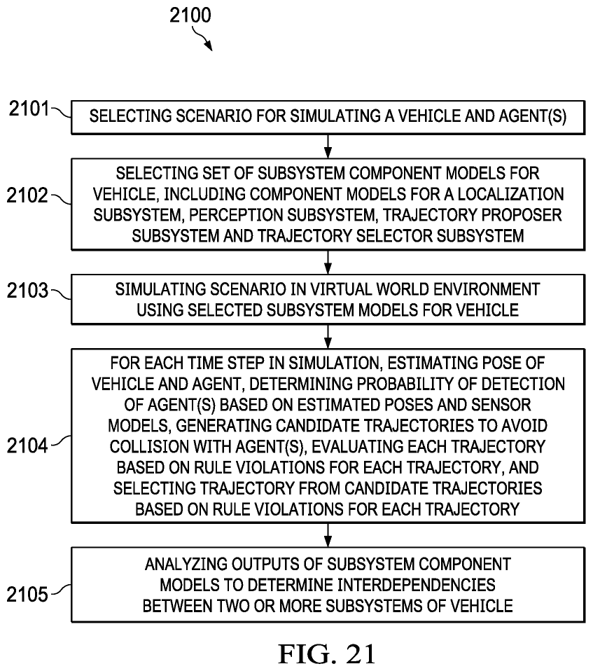

FIG. 21 is a flow diagram of a process 2100 for determining interdependencies of subsystems of a vehicle. Process 2100 can be implemented as described in reference to FIGS. 5 and 6.

In an embodiment, process 2100 includes the steps of: selecting a scenario for simulating a vehicle and at least one agent in a virtual world environment (2101); selecting a set of subsystem component models for the vehicle (2102), wherein the subsystems include a localization subsystem component model, a perception subsystem component model, a trajectory proposer subsystem component model, and trajectory selector subsystem component model; simulating the scenario in the virtual world environment using the selected subsystem component models (2103), wherein the simulating comprises: estimating a pose of the vehicle and the at least one agent based on the localization subsystem component model (2104); determining a probability of detection of the at least one agent by at least one sensor of the vehicle based on the perception subsystem component model, the estimated pose of the vehicle, the estimated pose of the at least one agent and a latency model modeling latency of a message queuing network for communicating data between the subsystems (2105); generating a set of candidate trajectories for the vehicle to avoid a collision with the at least one agent based on the trajectory proposer subsystem component model (2106); evaluating each trajectory based on a number of rule violations associated with the trajectory (2107); selecting one trajectory from the set of trajectories based on the number of rule violations for each candidate trajectory based on the trajectory selector subsystem component model (2108); and analyzing outputs of the subsystem component models to determine interdependencies between two or more subsystems of the vehicle (2109). Each of these steps are described in detail in reference to FIGS. 5-20.

In the foregoing description, aspects and embodiments of the present disclosure have been described with reference to numerous specific details that can vary from implementation to implementation. Accordingly, the description and drawings are to be regarded in an illustrative rather than a restrictive sense. The sole and exclusive indicator of the scope of the invention, and what is intended by the applicants to be the scope of the invention, is the literal and equivalent scope of the set of claims that issue from this application, in the specific form in which such claims issue, including any subsequent correction. Any definitions expressly set forth herein for terms contained in such claims shall govern the meaning of such terms as used in the claims. In addition, when we use the term “further comprising,” in the foregoing description or following claims, what follows this phrase can be an additional step or entity, or a sub-step/sub-entity of a previously-recited step or entity.

What is claimed is:

1. A method comprising:
selecting, with at least one processor, a scenario for simulating a vehicle and at least one agent in a virtual world environment;
selecting, with the at least one processor, a set of subsystem component models for the vehicle, wherein the subsystem component models include a localization subsystem component model, a perception subsystem component model, a trajectory proposer subsystem component model, and trajectory selector subsystem component model;
simulating, with the at least one processor, the scenario in the virtual world environment using the selected subsystem component models, wherein the simulating comprises:
estimating a pose of the vehicle and the at least one agent based on the localization subsystem component model;
determining a probability of detection of the at least one agent by at least one sensor of the vehicle based on the perception subsystem component model, the estimated pose of the vehicle, the estimated pose of the at least one agent and a latency model modeling latency of a message queuing network for communicating data between the subsystems;
generating, with the at least one processor, a set of candidate trajectories for the vehicle to avoid a collision with the at least one agent based on the trajectory proposer subsystem component model;
evaluating, with the at least one processor, each trajectory based on a number of rule violations associated with the trajectory;
selecting, with the at least one processor, one trajectory from the set of trajectories based on the number of rule violations for each candidate trajectory; and
analyzing, with the at least one processor, outputs of the subsystem component models to determine interdependencies between two or more subsystems of the vehicle.

2. The method of claim 1, wherein the simulating includes Monte Carlo simulations.

3. The method of claim 1, wherein the latency model includes performing a discrete-event simulation of the message queuing network, and a simulated event is selected based on a probability distribution for the event.

4. The method of claim 1, wherein the localization subsystem component model includes a covariance matrix for vehicle pose error, a computation time and task period.

5. The method of claim 1, wherein the perception subsystem component model includes a recall rate as a function of distance between the vehicle and the at least one agent and an agent detection at a previous time step of the simulation, a list of classes, a confusion matrix between the classes and a covariance matrix on the pose of the agent.

6. The method of claim 5, wherein the recall rate as a function of distance is based on a Markov model.

7. The method of claim 1, wherein the set of trajectories are generated randomly.

8. The method of claim 1, wherein the trajectory selector subsystem component model includes a rulebook that is used to rank the set of candidate trajectories and select a particular trajectory from the set of candidate trajectories based on the ranking.

9. The method of claim 1, wherein analyzing outputs of the subsystem component models to determine interdependencies between two or more of the subsystem component models, further comprises:
comparing a number of rule violations with a probability of detection.

10. The method of claim 1, wherein analyzing outputs of the subsystem component models to determine interdependencies between two or more of the subsystem component models, further comprises:
comparing a perception period for the perception subsystem with a recall error slope.

11. The method of claim 1, wherein analyzing outputs of the subsystem component models to determine interdependencies between two or more of the subsystem component models, further comprises:
comparing localization error with a select period for the trajectory selector subsystem.

12. The method of claim 1, wherein analyzing outputs of the subsystem component models to determine interdependencies between two or more of the subsystem component models, further comprises:
comparing localization error with a recall error slope.

13. The method of claim 1, wherein analyzing outputs of the subsystem component models to determine interdependencies between two or more of the subsystem component models, further comprises:
generating a correlation heat map that correlates subsystem model parameters with number of rule violations.

14. The method of claim 1, wherein analyzing outputs of the subsystem component models to determine interdependencies between two or more of the subsystem component models, further comprises:
comparing degrees of violation of at least two rules.

15. A system comprising:
at least one processor; and
memory storing instructions that when executed by the at least one processor, cause the at least one processor to perform operations comprising:
selecting a scenario for simulating a vehicle and at least one agent in a virtual world environment;
selecting a set of subsystem component models for the vehicle, wherein the subsystem component models include a localization subsystem component model, a perception subsystem component model, a trajectory proposer subsystem component model, and trajectory selector subsystem component model;
simulating the scenario in the virtual world environment using the selected subsystem component models, wherein the simulating comprises:
estimating a pose of the vehicle and the at least one agent based on the localization subsystem component model;
determining a probability of detection of the at least one agent by at least one sensor of the vehicle based on the perception subsystem component model, the estimated pose of the vehicle, the estimated pose of the at least one agent and a latency model modeling latency of a message queuing network for communicating data between the subsystems;
generating a set of candidate trajectories for the vehicle to avoid a collision with the at least one agent based on the trajectory proposer subsystem component model;
evaluating each trajectory based on a number of rule violations associated with the trajectory;
selecting one trajectory from the set of trajectories based on the number of rule violations for each candidate trajectory; and
analyzing outputs of the subsystem component models to determine interdependencies between two or more subsystems of the vehicle.

16. The system of claim 15, wherein the latency model includes performing a discrete-event simulation of the message queuing network, and a simulated event is selected based on a probability distribution for the event.

17. The system of claim 15, wherein the localization subsystem component model includes a covariance matrix for vehicle pose error, a computation time and task period.

18. The system of claim 15, wherein the perception subsystem component model includes a recall rate as a function of distance between the vehicle and the at least one agent and an agent detection at a previous timestep of the simulation, a list of classes, a confusion matrix between the classes and a covariance matrix on the pose of the agent.

19. The system of claim 15, wherein the trajectory selector subsystem component model includes a rulebook that is used to rank the set of candidate trajectories and select a particular trajectory from the set of candidate trajectories based on the ranking.

20. The system of claim 15, wherein analyzing outputs of the subsystem component models to determine interdependencies between two or more of the subsystem component models, further comprises:
comparing a number of rule violations with a probability of detection.

21. The system of claim 15, wherein analyzing outputs of the subsystem component models to determine interdependencies between two or more of the subsystem component models, further comprises:
comparing a perception period for the perception subsystem with a recall error slope.

22. The system of claim 15, wherein analyzing outputs of the subsystem component models to determine interdependencies between two or more of the subsystem component models, further comprises:
comparing localization error with a select period for the trajectory selector subsystem.

23. The system of claim 15, wherein analyzing outputs of the subsystem component models to determine interdependencies between two or more of the subsystem component models, further comprises:
comparing localization error with a recall error slope.

24. The system of claim 15, wherein analyzing outputs of the subsystem component models to determine interdependencies between two or more of the subsystem component models, further comprises:
generating a correlation heatmap that correlates subsystem model parameters with number of rule violations.

25. The system of claim 15, wherein analyzing outputs of the subsystem component models to determine interdependencies between two or more of the subsystem component models, further comprises:
comparing degrees of violation of at least two rules.
